(19) United States
(12) Patent Application Publication
(10) Pub. No.: US 2014/0102767 A1
(43) Pub. Date: Apr. 17, 2014

(54) MULTI-LAYER TYPE PRINTED CIRCUIT BOARD AND METHOD OF MANUFACTURING THE SAME

(71) Applicant: SAMSUNG ELECTRO-MECHANICS CO., LTD., Suwon (KR)

(72) Inventors: Myung Sam Kang, Suwon (KR); Ki Hwan Kim, Suwon (KR); Yong Yoon Cho, Suwon (KR); Sung Won Jeong, Suwon (KR); Sang Hyuck Oh, Suwon (KR); Da Hee Kim, Suwon (KR); Yoong Oh, Suwon (KR); Ki Young Yoo, Suwon (KR)

(73) Assignee: SAMSUNG ELECTRO-MECHANICS CO., LTD., Suwon (KR)

(21) Appl. No.: 13/845,092

(22) Filed: Mar. 18, 2013

(30) Foreign Application Priority Data
Oct. 15, 2012 (KR) 10-2012-0114356

(51) Int. Cl. H05K 1/02; H05K 3/00

(52) U.S. Cl. CPC H05K 1/0298; H05K 3/0064
USPC 174/251; 216/13; 156/150

(57) ABSTRACT

Disclosed herein is a multi-layer type printed circuit board, including; a first insulating layer including at least one first pillar; a plurality of insulating layers laminated in a both surfaces direction of the first insulating layer, each including at least one circuit layer and at least another pillar connected to the circuit layer; and a plurality of outermost circuit layers disposed on an outer surface of the outermost insulating layer, while contacting an outermost pillar disposed on an outermost insulating layer among the plurality of insulating layers, wherein the circuit layer and another pillar each formed in a both surfaces direction of the first insulating layer are disposed in a symmetrical form to each other based on the first insulating layer.

### CROSS REFERENCE TO RELATED APPLICATION

This application claims the benefit of Korean Patent Application No. 10-2012-0114356, filed on Oct. 15, 2012, entitled “Multi-Layer Type Printed Circuit Board And Method Of Manufacturing The Same”, which is hereby incorporated by reference in its entirety into this application.

### BACKGROUND OF THE INVENTION

1. Technical Field

The present invention relates to a multi-layer type printed circuit board and a method of manufacturing the same.

2. Description of the Related Art

Generally, a printed circuit board is implemented by wiring a copper foil on one surface or both surfaces of a board made of various kinds of thermosetting synthetic resins, fixing IC or electronic components on the board, and implementing electrical wirings therebetween and then, coating the electrical wirings with an insulator.

Recently, with the development of electronic industries, a demand for multi-functional and light and small electronic components has been rapidly increased. Accordingly, there is a need to increase a wiring density of a printed circuit board on which the electronic components are mounted and reduce a thickness thereof.

In particular, in order to cope with the thinness of the printed circuit board, a coreless substrate with the reduced thickness and signal processing time by removing a core substrate has been spotlighted.

In case of the coreless substrate, since the core substrate is removed, a carrier member serving as a support during a manufacturing process is required. An upper substrate and a lower substrate are separated from each other by forming a buildup layer including circuit layers and insulating layers on both surfaces of the carrier member according to a method of manufacturing a substrate of the prior art and removing the carrier member, such that the coreless substrate is completed.

As described in Patent Document 1, the method of manufacturing a coreless printed circuit board according to the prior art performs a laser direct ablation (LDA) method for forming opening parts on an insulating layer as a previous stage for forming vias for electrical connection of each buildup layer.

However, the LDA method may cause an increase in machining time due to a limitation of a laser spot size when a size of the opening part is large.

Further, the method of manufacturing a coreless printed circuit board according to the prior art need to perform laser machining several times, thereby increasing complexity and costs of process.

### RELATED ART DOCUMENT

### Patent Document

(Patent Document 1) Korean Patent Laid-Open Publication No. 2010-0043547 (laid-open published on Apr. 29, 2010)

### SUMMARY OF THE INVENTION

The present invention has been made in an effort to provide a multi-layer type printed circuit board including a pillar for electrical connection using a dry film.

Further, the present invention has been made in an effort to provide a method of manufacturing a multi-layer type printed circuit board including a pillar for electrical connection using a dry film.

According to a preferred embodiment of the present invention, there is provided a multi-layer type printed circuit board, including: a first insulating layer including at least one first pillar; a plurality of insulating layers laminated in a both surfaces direction of the first insulating layer, each including at least one circuit layer and at least another pillar connected to the circuit layer; and a plurality of outermost circuit layers disposed on an outer surface of the outermost insulating layer, while contacting an outermost pillar disposed on an outermost insulating layer among the plurality of insulating layers, wherein the circuit layer and another pillar each formed in a both surfaces direction of the first insulating layer are disposed in a symmetrical form to each other based on the first insulating layer.

The first insulating layer may include a glass cloth and the first insulating layer and the plurality of insulating layers may be made of different materials.

The plurality of insulating layers may have a surface roughness disposed on a surface on which the circuit layer is provided.

The circuit layer and another pillar each may be sequentially laminated in a both surfaces direction based on a first pillar of the first insulating layer and may be provided in a symmetrical form to each other based on the first pillar.

The outermost circuit layer may be provided with a first surface treating film of any one of an organic solderability preservative (OSP) treating film, a black oxide film, and a brown oxide film, instead of a solder resist (SR) or a second surface treating film of any one of a gold plating film, an electrolytic gold plating film, an electroless gold plating film, or an electroless nickel immersion gold (ENIG) film.

According to another preferred embodiment of the present invention, there is provided a method of manufacturing a multi-layer type printed circuit board, including: (A) preparing a carrier substrate including at least one copper foil disposed on one surface or both surfaces of an insulating plate; (B) forming a multi-layer type printed circuit board precursor on one surface or both surfaces of the carrier substrate; (C) separating the carrier substrate; and (D) laminating a plurality of other insulating layers sequentially including other circuit layers and other pillars on an outer surface of the multi-layer printed circuit board precursor.

The method of manufacturing a multi-layer type printed circuit board may further include: (E) forming an outermost circuit layer on an outermost insulating layer of the other insulating layers; and (F) forming a first surface treating film or a second surface treating film on the outermost circuit layer.

The first surface treating film may be formed of any one of an organic solderability preservative (OSP) treating film, a black oxide film, and a brown oxide film, instead of a solder resist (SR), and the second surface treating film may be formed of any one of a gold plating film, an electrolytic gold plating film, an electroless gold plating film, and electroless nickel immersion gold (ENIG) film.

The step (B) may include: (B-1) forming a plurality of first pillars by performing the electrolytic copper plating on a first dry film pattern formed on one surface or both surfaces of the carrier substrate; (B-2) peeling off the first dry film pattern; (B-3) forming a first insulating layer having a thickness equal to or larger than a height of the first pillar on one surface or both surfaces of the carrier substrate; (B-4) performing a polishing and cutting process on the first insulating layer so as to expose the first pillar; (B-5) forming a seed layer on the outer surface of the first insulating layer on which the first pillar is exposed by using a PVD or CVD method; (B-6) forming a dry film pattern for forming a first circuit layer on the seed layer; (B-7) forming the first circuit layer by plating and peeling off copper on the dry film pattern for forming the first circuit layer; (B-8) forming a second dry film pattern on the outer surface of the first insulating layer including the first circuit layer; (B-9) forming a second pillar connected with the first circuit layer by plating and peeling off copper on the second dry film pattern; (B-10) removing a non-overlapping seed layer on the first circuit layer by etching so as to form an overlapping seed pattern on the first circuit layer; (B-11) forming a second insulating layer having a thickness equal to or larger than the overall height from the seed pattern to the second pillar; and (B-12) performing the polishing and cutting process on the second insulating layer so as to expose the second pillar.

In steps (B-1), (B-7), and (B-9), the copper may be plated by any one of CVD, PVD, a subtractive method, an additive method using electroless copper plating or electrolytic copper plating, SAP and MSAP.

The insulating layer of the multi-layer type printed circuit board may be formed, including a glass cloth and the insulating layer of the multi-layer type printed circuit board precursor and the other insulating layers may be made of different materials.

The step (D) may include performing desmear treatment on the other insulating layers.

The steps (B-4) and (B-12) may be performed by using any one of belt-sander, end-mill, ceramic buff, and chemical mechanical polishing (CMP).

The step (B) may include: (B-1) forming a plurality of first pillars by plating copper on a first dry film pattern formed on one surface or both surfaces of the carrier substrate; (B-2) peeling off the first dry film pattern; (B-3) forming a first insulating layer having a thickness equal to or larger than a height of the first pillar on one surface or both surfaces of the carrier substrate; and (B-4) performing a polishing and cutting process on the first insulating layer so as to expose the first pillar.

In step (B-1), the copper may be plated by any one of CVD, PVD, a subtractive method, an additive method using electroless copper plating or electrolytic copper plating, SAP and MSAP.

The step (B-4) may be performed by using any one of belt-sander, end-mill, ceramic bug and chemical mechanical polishing (CMP).

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of a multi-layer type printed circuit board according to a preferred embodiment of the present invention;

FIGS. 2A to 2N are cross-sectional views for sequentially describing the processes of a method of manufacturing a multi-layer type printed circuit board according to a preferred embodiment of the present invention; and

FIGS. 3A to 3E are cross-sectional views for sequentially describing the processes of a method of manufacturing a multi-layer type printed circuit board according to another preferred embodiment of the present invention.

### DESCRIPTION OF THE PREFERRED EMBODIMENTS

The above and other objects, features and advantages of the present invention will be more clearly understood from preferred embodiments and the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted. In the description, the terms “first”, “second”, and so on are used to distinguish one element from another element, and the elements are not defined by the above terms.

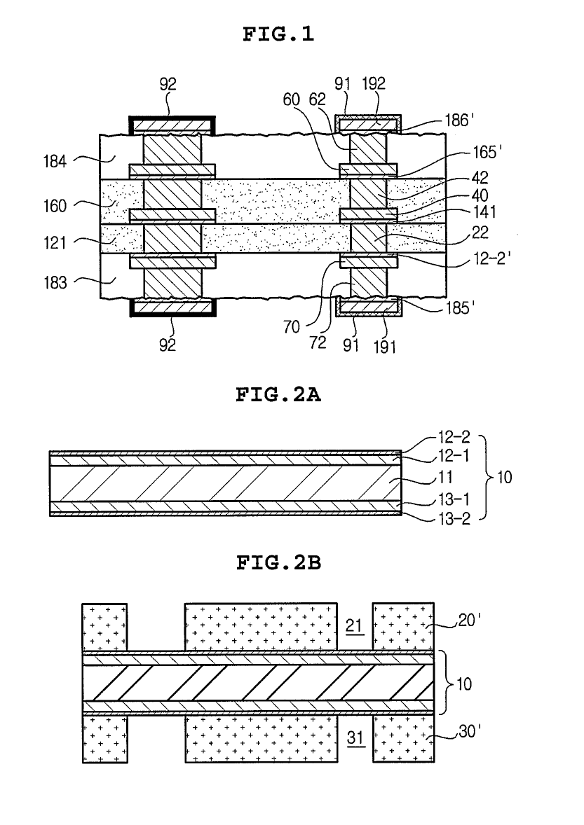

Hereinafter, preferred embodiments of the present invention will be described in detail with reference to the accompanying drawings. FIG. 1 is a cross-sectional view of a multi-layer type printed circuit board according to a preferred embodiment of the present invention. Herein, a multi-layer type printed circuit board according to a preferred embodiment of the present invention will be described with reference to, for example, a printed circuit board including four insulating layers. Further, the preferred embodiment of the present invention may also be applied to the printed circuit board having a multi-layer buildup structure including four or more insulating layers.

The multi-layer type printed circuit board according to the first preferred embodiment of the present invention includes a first insulating layer 121, a second upper insulating layer 160, a third upper insulating layer 184, and a second lower insulating layer 183, wherein a first upper circuit layer 40 and a second upper circuit layer 60 are each provided so as to be symmetrical with a first lower circuit layer 70 and a bottom circuit layer 191, based on the first insulating layer 121.

The multi-layer printed circuit board according to the first preferred embodiment of the present invention includes a plurality of pillars 72, 22, 42, and 62 electrically connecting each circuit pattern from the bottom circuit layer 191 to a top circuit layer 192 and includes a first surface treating film 91 covering the bottom circuit layer 191 or the top circuit layer 192 instead of a solder resist (SR) so as to improve anti-oxidation and soldering of the bottom circuit layer 191 or the top circuit layer 192 or a second surface treating film 92 to increase electrical conductivity so as to improve connection reliability with external devices.

Further, in the multi-layer type printed circuit board according to the first preferred embodiment of the present invention, the third upper insulating layer 184 and the second lower insulating layer 183 may be formed as an insulating layer of made of a material different from that of the first insulating layer 121 and the second upper insulating layer 160.

That is, the first insulating layer 121 and the second upper insulating layer 160 may be formed as an insulating layer including a glass cloth, while the third upper insulating layer 184 and the second lower insulating layer 183 may be formed as an insulating layer including a material such as resin, and the like, without including a glass cloth.

In particular, the third upper insulating layer 184 and the second lower insulating layer 183 may be each subjected to desmear treatment to form a surface on which the bottom circuit layer 191 is formed or a surface on which the top circuit layer 192 is formed as a surface having surface roughness.

Therefore, the third upper insulating layer 184 and the second lower insulating layer 183 may be formed as the surface having the surface roughness to form a bottom seed layer 185′ and a top seed layer 186′ by a copper plating process using electroless chemical copper, differently from a seed layer 165′ formed by using a PVD or CVD process.

Next, the bottom circuit layer 191 and the top circuit layer 192 may be formed using the bottom seed layer 185′ and the top seed layer 186′.

Further, the multi-layer type printed circuit board according to the first preferred embodiment of the present invention may include at least one insulating layer such as the first insulating layer 121 including only the first pillar 22 without including the circuit patterns and may be symmetrically provided with the plurality of circuit layers and the pillars in a vertical direction based on the insulating layer.

In detail, the plurality of circuit layers 40, 60, 70, 80, and 90 or the plurality of pillars 22, 42, 62, and 72 may be formed using a dry film pattern, for example, methods such as vapor deposition methods such as chemical vapor deposition (CVD), physical vapor deposition (PVD), and the like, a subtractive method, an additive method using electroless copper plating or electrolytic copper plating, and a semi-additive process (SAP), a modified semi-additive process (MSAP), and the like.

The plurality of circuit layers 40, 60, 70, 80, and 90 or the pillars 22, 42, 62, and 72 are provided to have a symmetrical structure to each other based on the first insulating layer 121 and the second upper insulating layer 160 to improve the circuit density of the multi-layer type printed circuit board, in particular, implement the electrical connection using the easily formed pillar instead of the vias of the prior art.

The first surface treating film 91 may be formed of any one of an organic solderability preservative (OSP) treating film, a black oxide film, and a brown oxide film. In particular, the OSP treating film is divided into an organic solvent type and a water soluble type, wherein the organic solvent type may be formed on a surface of the bottom circuit layer 191 or the top circuit layer 192 using roll coating, spray coating, and the like. Further, the water soluble type may be formed on both of the bottom circuit layer 191 and the top circuit layer 192 or any one of the bottom circuit layer 191 and the top circuit layer 192 by using a dipping method.

Further, the second surface treating film 92 may be formed as a film of a metal material having high electric conductivity, for example, may be formed of a gold plating film, an electroless gold plating film, or an electroless nickel immersion gold (EMG) film.

In particular, the EMG film may be formed by plating nickel with an electroless plating process and then, plating immersion gold and has excellent heat resistance and solderability.

The first surface treating film 91 and the second surface treating film 92 are not limited to the above examples and may include hot air solder leveling (HASL) or all the other plating layers.

The multi-layer type printed circuit board according to the first preferred embodiment of the present invention may be easily provided with the buildup layer structure configured of the plurality of insulating layers and the plurality of pillars for electrically connecting the buildup layers by using a carrier and the dry film.

According to the preferred embodiments of the present invention, the multi-layer type printed circuit board can easily include the pillar for electrical connection instead of the vias formed by the laser according to the prior art, thereby saving the manufacturing costs and improving the integration of the circuit.

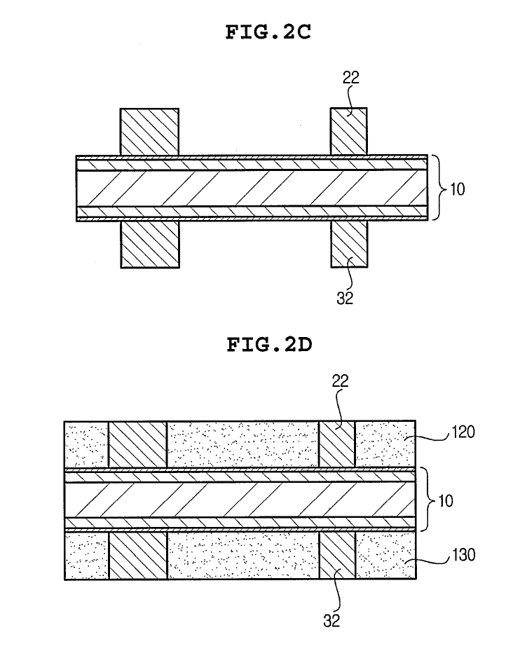

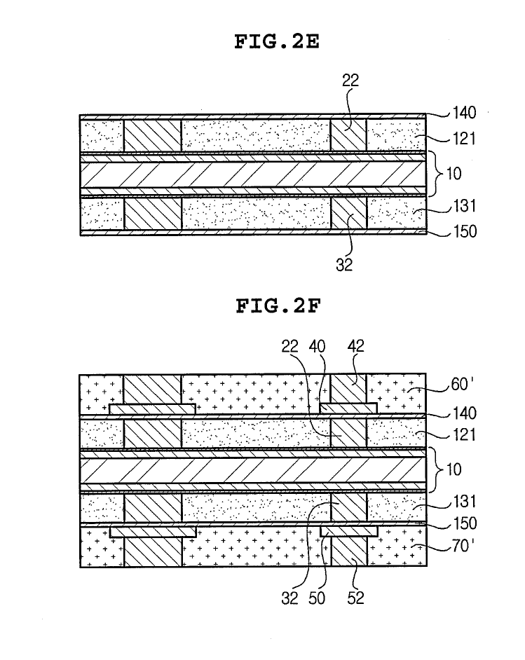

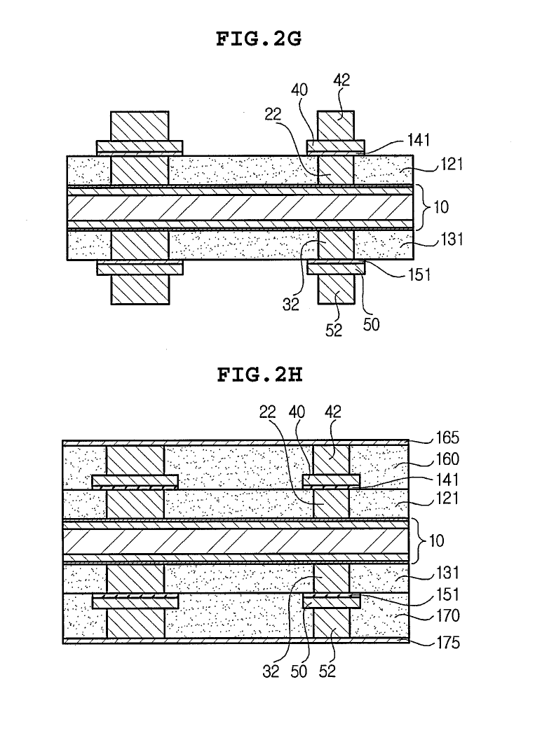

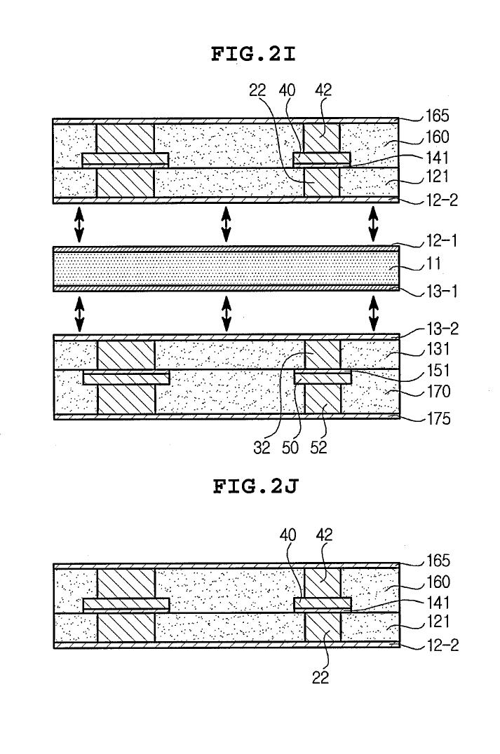

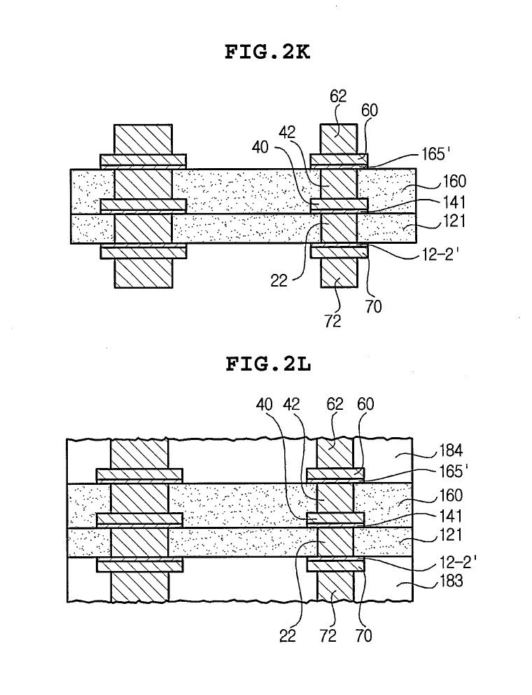

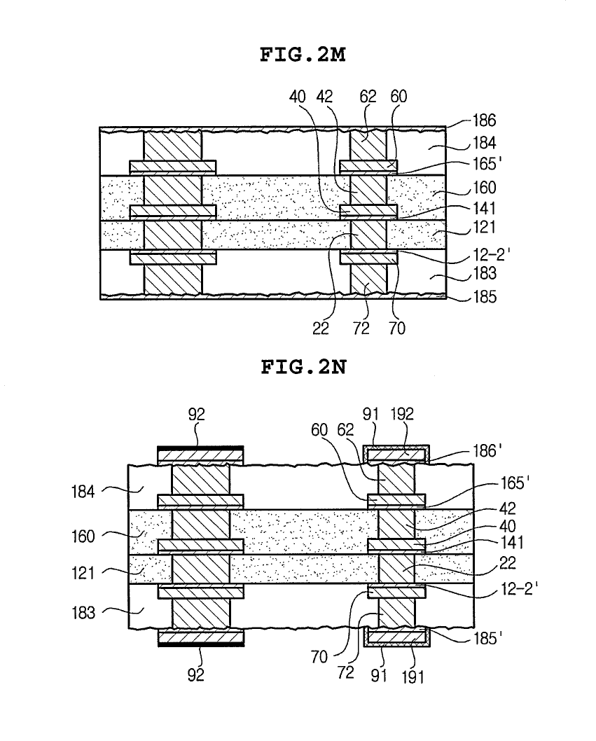

Hereinafter, a method of manufacturing a multi-layer type printed circuit board according to the preferred embodiment of the present invention will be described with reference to FIGS. 2A to 2N. FIGS. 2A to 2N are cross-sectional views for sequentially describing the processes of a method of manufacturing a multi-layer type printed circuit board according to a preferred embodiment of the present invention.

As illustrated in FIG. 2A, according to the method of manufacturing a multi-layer type printed circuit board according to the preferred embodiment of the present invention, a carrier substrate 10 is first prepared.

The carrier substrate 10 has, for example, a structure in which two copper foils are laminated on one surface or both surfaces of the insulating plate 11 and serves to support the a printed circuit board during the manufacturing process. The preferred embodiment of the present invention describes that the carrier substrate 10 has a structure that two copper foils are disposed on both surfaces of the insulating plate 11, but is not limited thereto and two or more copper foils may each be disposed on both surfaces of the insulating plate 11 while having a thickness difference.

In detail, the insulating plate 11 of the carrier substrate 10 is made of for example, thermosetting resin such as epoxy resin, thermoplastic resin such as polyimide, as resin materials or prepreg in which stiffeners such as glass fiber or inorganic filler are impregnated therein.

For the insulating plate 11, a first upper copper foil 12-1 and a second upper copper foil 12-2 are disposed on the insulating plate 11 and a first lower copper foil 13-1 and a second lower copper foil 13-2 is disposed beneath the insulating plate 11.

Optionally, a release layer is disposed between the first upper copper foil 12-1 and the second upper copper foil 12-2 or is disposed between the first lower copper foil 13-1 and the second lower copper foil 13-2, thereby easily implement the separation of the carrier substrate 10 during the subsequent process.

For example, the release layer is made of an adhesion material of a polymer material selected from a group consisting of borons, silicons, polyethylene terephthalate, polymethylpentene, and a combination thereof, but the preferred embodiment of the present invention is not limited thereto.

After the carrier substrate 10 is prepared, as illustrated in FIG. 2B, first dry film patterns 20′ and 30′ having a plurality of openings 21 and 31 are formed on both surfaces of the carrier substrate 10.

In detail, in a process of forming the first dry film patterns 20′ and 30′, the dry films are laminated on both surfaces of the carrier substrate 10 by using a laminator.

Next, the dry film is optionally cured by an exposure process of exposing the dry film to light and melts only a portion which is not cured with a developer and may be patterned as the first upper dry film pattern 20′ having the upper opening 21 and the first lower dry film pattern 30′ having the lower opening 31, as illustrated in FIG. 2B.

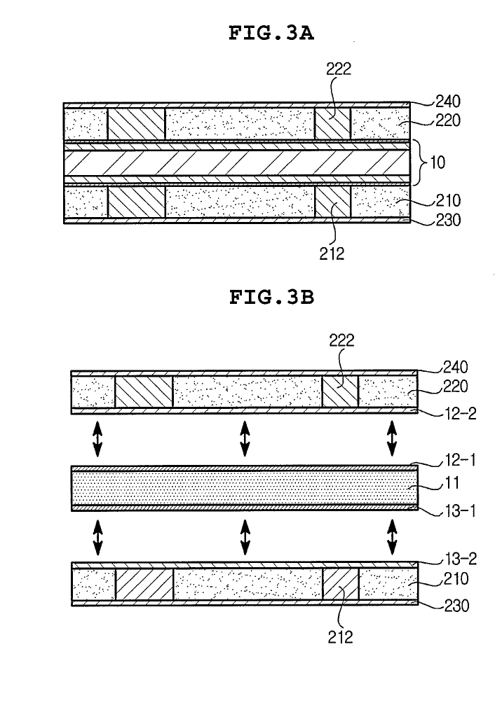

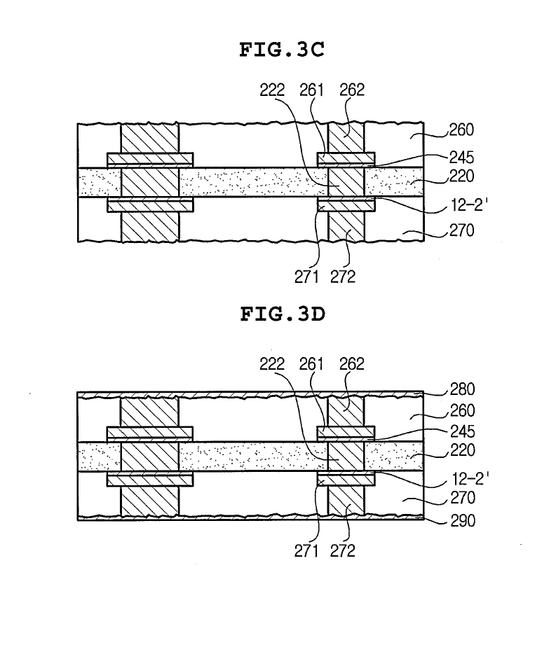

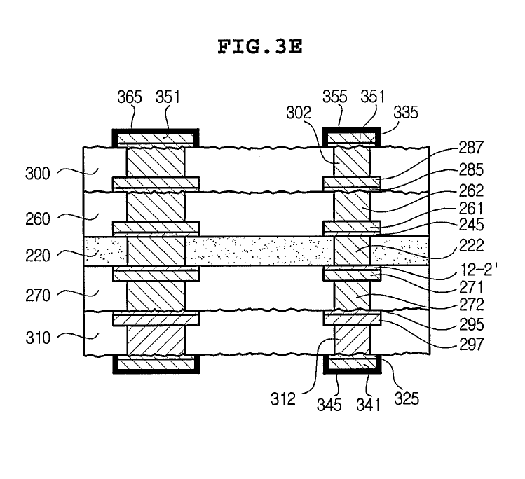

After the first dry film patterns 20′ and 30′ having the plurality of openings 21 and 31 are formed, as illustrated in FIG. 3C, the upper opening part 21 and the lower opening part 31 are plated with copper by the electrolytic copper plating method to form the first pillar 22 and a first dummy pillar 32 that is the same as the first pillar 22.

Next, the first dry film patterns 20′ and 30′ are peeled off by a stripping liquid and as illustrated in FIG. 2C, the first pillar 22 and the first dummy pillar 32 that is the same as the first pillar 22 are disposed in plural on an upper surface and a lower surface of the carrier substrate 10. Here, an example of the stripping solution for removing the dry film patterns 20 and 30 may include alkali metal hydroxides, and the like.

After the first pillar 22 and the first dummy pillar 32 are disposed in plural on the upper surface and the lower surface of the carrier substrate 10, as illustrated in FIG. 2D, the first film 120 of the first insulating layer and the film 130 of the first dummy insulating layer that is the same as the film 120 of the first insulating layer are laminated on the upper surface and the lower surface of the carrier substrate 10, respectively.

In detail, the film 120 of the first insulating film and the film 130 of the first dummy insulating layer that are formed of the same material each including a glass cloth are laminated on the upper surface and the lower surface of the carrier substrate 10 by using a laminator and laminated so that the thickness thereof are each equal to or larger than the height of the first pillar 22 and the first dummy pillar 32.

Therefore, the first pillar 22 and the first dummy pillar 32 may each be exposed to the outside by penetrating through the film 120 of the first insulating layer and the film 130 of the first dummy insulating layer.

Next, a polishing and cutting process is performed on the film 120 of the first insulating layer including the first pillar 22 and the film 130 of the first dummy insulating layer including the first dummy pillar 32, which are exposed or are not exposed.

In detail, the polishing and cutting process on the film 120 of the first insulating layer and the film 130 of the first dummy insulating layer may use a polishing process using belt-sander, end-mill, or ceramic buff or a chemical mechanical polishing (CMP) process.

Therefore, the first insulating layer 121 of the flat surface including the first pillar 22 and the first dummy insulating layer 131 of the flat surface including the first dummy pillar 32 may be formed.

After the polishing and cutting process is performed, as illustrated in FIG. 2E, a first seed layer 140 and a first dummy seed layer 150 are formed on the upper surface of the first insulating layer 121 on which the first pillar 22 is exposed and on the lower surface of the first dummy insulating layer 131 on which the first dummy pillar 32 is exposed, respectively.

In detail, the first seed layer 140 and the first dummy seed layer 150 may be formed as a metal layer using the vapor deposition method such as CVD or PVD, for example, may also be formed to have a two-layer structure of a Ti layer/Cu layer by a sputtering process among the vapor deposition methods of the PVD.

After the first seed layer 140 and the first dummy seed layer 150 are formed, as illustrated in FIG. 2F, the first circuit layer 40 and the first dummy circuit layer 50 that is the same as the first circuit layer 40 are formed by using the methods such as SAP, MSAP, and the like.

Next, a second upper dry film pattern 60′ and a second lower dry film pattern 70′ are formed on the upper surface of the first seed layer 140 on which the first circuit layer 40 is formed and on the lower surface of the first dummy seed layer 150 on which the first dummy circuit layer 50 is formed, respectively. Here, the second upper dry film pattern 60′ and the second lower dry film pattern 70′ are each provided with a plurality of opening parts for forming the second pillar 42 and a second dummy pillar 52 by the exposing and developing processes.

The second pillar 42 and the second dummy pillar 52 are formed by performing any one of the vapor deposition method such as CVD, PVD, and the like, the subtractive method, the additive method using electroless copper plating and electrolytic copper plating, and the methods such as SAP, MSAP, and the like, on the second upper dry film pattern 60′ and the second lower dry film pattern 70′.

In this case, the remaining portion other than the first seed layer 140 of the lower portion of the first circuit layer 40 by performing the patterning on the first seed layer 140 is removed by the etching to form a structure in which the first pillar 22 of the first insulating layer 121 is sequentially laminated with a first seed pattern 141, the first circuit layer 40, and the second pillar 42 as illustrated in FIG. 2G.

Similarly, even in the case of the first dummy seed layer 150 that is the same as the first seed layer 140, a first dummy seed pattern 151, the structure in which the first dummy circuit layer 50, and the second dummy pillar 52 are sequentially laminated from the first dummy pillar 32 of the first dummy insulating layer 131 is formed.

Similar to applying the same lamination process using the foregoing laminator to each of the first insulating layer 121 including the second pillar 42 and the first dummy insulating layer 131 including the second dummy pillar 52, the second upper insulating layer 160 and the second dummy insulating layer 170 are each laminated on the first insulating layer 121 and the first dummy insulating layer 131.

In this case, the lamination may be performed so that the thickness of the second upper insulating layer 160 is equal to or larger than the height from the first seed pattern 141 to the second pillar 42 and the thickness of the second dummy insulating layer 170 is equal to or larger than the height from the first dummy seed pattern 151 to the second dummy pillar 52.

Therefore, as illustrated in FIG. 2H, the second pillar 42 and the second dummy pillar 52 that is the same as the second pillar 42 may each be exposed to the outside by penetrating through the second upper insulating layer 160 and the second dummy insulating layer 170.

Thereafter, the polishing and cutting process is performed on the second upper insulating layer 160 including the second pillar 42 and the second dummy insulating layer 170 including the second dummy pillar 52 and as illustrated in FIG. 2H, the second upper insulating layer 160 and the second dummy insulating layer 170 planarized by the polishing and cutting process may be each formed with the second seed layer 165 and the second dummy seed layer 175.

Here, similar to the first seed layer 140, the second seed layer 140 and the second dummy seed layer 175 may be formed as a metal layer using the vapor deposition method such as CVD or PVD, for example, may also be formed to have a two-layer structure of a Ti layer/Cu layer by a sputtering process among the vapor deposition methods of the PVD.

Next, as illustrated in FIG. 2I, the routing is performed on the carrier substrate 10 to separate an upper multi-layer type printed circuit board precursor including the second upper copper foil 12-2 and a lower multi-layer printed circuit board precursor including the second lower copper foil 13-2.

In this case, the upper multi-layer type printed circuit board precursor and the lower multi-layer type printed circuit board precursor may be more easily separated by the release layer previously disposed between the first upper copper foil 12-1 and the second upper copper foil 12-2 or between the first lower copper foil 13-1 and the second lower copper foil 13-2.

The plurality of insulating layers including the circuit layers and the pillars are laminated on the upper multi-layer type printed circuit board precursor and the lower multi-layer type printed circuit board precursor, respectively, that are separated from each other as described above, thereby manufacturing the multi-layer type printed circuit board having the buildup structure.

For describing the process, as illustrated in FIG. 2J, the subsequent process will be described with reference to the upper multi-layer type printed circuit board structure including the second pillar 42. Further, the subsequent process to be described below may be identically applied to the lower multi-layer type printed circuit board structure including the second dummy pillar 52.

As illustrated in FIG. 2K, for the separated upper multi-layer type printed circuit board structure, the first lower circuit layer 70 and a fourth pillar 72 are sequentially formed on the lower surface of the first insulating layer 121 exposing the first pillar 22 and the second upper circuit layer 60 and a third pillar 62 are sequentially formed on the upper surface of the second upper insulating layer 160 exposing the second pillar 42.

In detail, similar to the process of forming the first upper circuit layer 40, the dry film patterns for forming the second upper circuit layer 60 and the first lower circuit layer 70 are formed on the second seed layer 165 and the second upper copper foil 12-2, respectively. In this case, the second upper copper foil 12-2 is used as the seed layer for forming the first lower circuit layer 70, such that there is no need to separately form the seed layer for forming the first lower circuit layer 70.

Any one of the methods such as the vapor deposition methods such as CVD, PVD, and the like, the subtractive method, the additive method using the electroless copper plating or the electrolytic copper plating, and the methods such as the SAP, the MSAP, and the like, is applied to the dry film patterns to form the second upper circuit layer 60 and the first lower circuit layer 70.

Next, similar to the process of forming the second pillar 42, the dry film pattern for forming the third pillar 62 and the dry film pattern for forming the fourth pillar 72 are provided and copper is plated by any one of the methods such as the vapor deposition methods such as CVD, PVD, and the like, the subtractive method, the additive method using the electroless copper plating or the electrolytic copper plating, and the methods such as the SAP, the MSAP, and the like, to form the third pillar 62 and the fourth pillar 72.

Next, the remaining portion other than the second seed layer 165 of the lower portion of the second upper circuit layer 60 is removed by the etching to form a structure in which the surface on which the second insulating layer 160 is exposed is sequentially laminated with a second seed pattern 165′, the second upper circuit layer 60, and the third pillar 62 as illustrated in FIG. 2K.

Further, the method is identically applied to the lower portion of the first insulating layer 121 to form the structure in which the second upper copper foil pattern 12-2′, the first lower circuit layer 70, and the fourth pillar 72 are sequentially laminated from the lower surface on which the first insulating layer 121 is exposed.

Next, the third upper insulating layer 184 and the second lower insulating layer 183 are formed on the upper surface of the second insulating layer 160 and the lower surface of the first insulating layer 121, corresponding to the third pillar 62 and the third dummy pillar 72 similar to the third pillar 62, respectively.

For example, the third upper insulating layer 184 and the second lower insulating layer 183 may be formed by laminating a non-cured film of an insulating material including a material such as resin, and the like, rather than including the glass cloth by the laminator.

Next, the third upper insulating layer 184 and the second lower insulating layer 183 are each subjected to the desmear treatment to expose the third pillar 62 and the fourth pillar 72 and include a surface on which the surface roughness is formed, as illustrated in FIG. 2I.

Next, as illustrated in FIG. 2M, each surface of the third upper insulating layer 184 and the second lower insulating layer 183 that are formed with the surface roughness is subjected to the electroless copper plating without using the PVD or CVD method to form the top seed layer 186 and the bottom seed layer 185. Here, the top seed layer 186 and the bottom seed layer 185 are subjected to the desmear treatment so as to be easily formed on each surface of the third upper insulating layer 184 and the second lower insulating layer 183 that are formed with the surface roughness.

Next, similar to the process of forming the circuit layers 60 and 70, the top seed layer 186 and the bottom seed layer 185 are each provided with the dry film patterns for the top circuit layer 192 and the bottom circuit layer 191.

For the dry film patterns for the top circuit layer 192 and the bottom circuit layer 191, copper is plated by any one of the vapor deposition method such as CVD, PVD, and the like, the subtractive method, the additive method using electroless copper plating and electrolytic copper plating, and the methods such as SAP, MSAP, and the like, to form the top circuit layer 192 and the bottom circuit layer 191 as illustrated in FIG. 2N.

After the top circuit layer 192 and the bottom circuit layer 191 are formed, the first surface treating film 91 or the second surface treating film 92 are formed on the top circuit layer 192 and the bottom circuit layer 191.

The first surface treating film 91 may be formed as any one of an organic solderability preservative (OSP) treating film, a black oxide film, and a brown oxide film, instead of a solder resist (SR) according to the prior art. Here, the OSP treating film is divided into an organic solvent type and a water soluble type, wherein the organic solvent type may be formed on a surface of the bottom circuit layer 185′ or top circuit layer 186′ using roll coating, spray coating, and the like, and the water soluble type may be formed by a dipping method. Further, the black oxide film or the brown oxide film may be formed by oxidizing the top circuit layer 186′ and the bottom circuit layer 185′ that are made of copper.

Further, the second surface treating film 92 may be formed as a film of a metal material having high electric conductivity, for example, may be formed of a gold plating film, an electroless gold plating film, or an electroless nickel immersion gold (EMG) film.

In particular, the EMG film may be formed by plating nickel with an electroless plating process and then, plating immersion gold.

Further, the first surface treating film 91 and the second surface treating film 92 are not limited to the above examples and may be formed as hot air solder leveling (HASL) or all the other surface treating layers.

According to the referred embodiment of the present invention, the method of manufacturing a multi-layer type printed circuit board can easily manufacture the printed circuit board including five circuit layers electrically connected by the plurality of pillars using the carrier substrate 10 and the dry film pattern, thereby resolving the problems of the machining time and the manufacturing costs occurring while forming the vias using a laser according to the related art. Here, the method of manufacturing a multi-layer printed circuit board according to the preferred embodiment of the present invention may be implemented as the multi-layer printed circuit board having five circuit layers and four insulating layers.

In particular, the method of manufacturing a coreless substrate according to the first preferred embodiment of the present invention can mass-produce the multi-layer type printed circuit board without causing warpage due to the use of the carrier substrate 10 and the dry film pattern.

Hereinafter, a method of manufacturing a multi-layer type printed circuit board according to another preferred embodiment of the present invention will be described with reference to FIGS. 3A to 3E. FIGS. 3A to 3E are cross-sectional views for sequentially describing the processes of a method of manufacturing a multi-layer type printed circuit board according to another preferred embodiment of the present invention.

Here, the method of manufacturing a multi-layer type coreless substrate according to another preferred embodiment of the present invention will be described with reference to a method of manufacturing a multi-layer type printed circuit board having even numbers of circuit layers such as six circuit layers 351, 285, 261, 271, 295, and 341. Therefore, in describing the method of manufacturing a multi-layer printed circuit board according to another preferred embodiment of the present invention, a portion similar to the method of manufacturing a multi-layer printed circuit board according to the preferred embodiment of the present invention will be omitted.

The method of manufacturing a multi-layer printed circuit board according to another preferred embodiment of the present invention, as illustrated in FIG. 3A, a first insulating layer 220 and a first dummy insulating layer 210 that is the same as the first insulating layer 220 are laminated on the upper and lower surfaces of the carrier substrate 10, respectively, that includes a plurality of first pillars 222 and a plurality of first dummy pillars 212 that are the same as the plurality of first pillars 222.

Next, the first insulating layer 220 including the first pillar 222 and the first dummy insulating layer 210 including the first dummy pillar 212 are subjected to the polishing and cutting process to form the first insulating layer 220 including the first pillar 222 and the first dummy insulating layer 210 including the first dummy pillar 212 as the flat surface.

A first seed layer 240 and the first dummy seed layer 230 that is the same as the first seed layer 240 are each formed on the upper surface of the first insulating layer 220 on which the first pillar 222 is exposed and the lower surface of the first dummy insulating layer 210 on which the first dummy pillar 212 is exposed by the PVD or CVD method.

Next, as illustrated in FIG. 3B, the routing is performed on the carrier substrate 10 to separate an upper multi-layer type printed circuit board precursor including the second upper to copper foil 12-2 and a lower multi-layer printed circuit board precursor including the second lower copper foil 13-2.

As described above, the separated upper multi-layer type printed circuit board structure and lower multi-layer type printed circuit board structure each use the precursor having the insulating layer structure having only the pillar disposed therein without the circuit layer, thereby manufacturing the multi-layer type printed circuit board having even numbers of circuit layers.

Next, a first upper circuit layer 261 and a first lower circuit layer 271 are symmetrically formed on the upper multi-layer printed circuit board structure by the copper plating etching process using the first seed layer 240 and the second upper copper foil 12-2.

In this case, the first seed layer 240 and the second upper copper foil 12-2 may be formed as a first seed pattern 245 and a second upper copper foil pattern 12-2′ for the first upper circuit layer 261 and the first lower circuit layer 271 by the etching process.

Next, after the dry film pattern having the opening parts each exposing the first upper circuit layer 261 and the first lower circuit layer 271 are formed, the opening parts are plated with copper by the electroless copper plating method to form the second upper pillar 262 and the second lower pillar 272.

Next, the dry film pattern is removed by peeling such that the second upper pillar 262 and the second lower pillar 272 each connected with the first upper circuit layer 261 and the first lower circuit layer 271 are implemented.

As described above, the structure of the second upper copper foil pattern 12-2′, the first lower circuit layer 271, and the second lower pillar 272 is symmetrically formed to the structure of the first seed pattern 245, the first upper circuit layer 261, and the second upper pillar 262 on both surfaces of the first pillar 222. Further, the same process may be performed on the lower multi-layer type printed circuit board structure.

Next, as illustrated in FIG. 3C, the second upper insulating layer 260 and the second lower insulating layer 270 are laminated on the second upper pillar 262 and the second lower pillar 272, respectively and are subjected to the desmear treatment.

Therefore, as illustrated in FIG. 3C, the second upper insulating layer 260 and the second lower insulating layer 270 are each subjected to the desmear treatment to include the surface on which the surface roughness is formed while exposing the second upper pillar 262 and the second lower pillar 272, respectively.

Next, as illustrated in FIG. 3D, each surface of the second upper insulating layer 260 and the second lower insulating layer 270 that are formed with the surface roughness is subjected to the electroless copper plating without using the PVD or CVD method to form the top seed layer 280 and the bottom seed layer 290. Here, the top seed layer 280 and the bottom seed layer 290 are subjected to the desmear treatment so as to be easily formed on each surface of the second upper insulating layer 260 and the second lower insulating layer 270 that are formed with the surface roughness.

Next, similar to the process of forming the circuit layers 261 and 271, the dry film patterns are formed on the second upper seed layer 280 and the second lower seed layer 290, respectively, to form a second upper circuit layer 287 and a second lower circuit layer 297.

For the dry film patterns for the top circuit layer 287 and the bottom circuit layer 297, copper is plated by any one of the vapor deposition method such as CVD, PVD, and the like, the subtractive method, the additive method using electroless copper plating and electrolytic copper plating, and the methods such as SAP, MSAP, and the like, to form the second top circuit layer 287 and the second bottom circuit layer 297 as illustrated in FIG. 3E.

In this case, the second top circuit layer 287 and the second lower circuit layer 297 each include the second upper seed pattern 285 and the second lower seed pattern 295.

As illustrated in FIG. 3E, the third upper pillar 302 and the third lower pillar 312 are formed on the second upper circuit layer 287 and the second lower circuit layer 297, respectively and the third upper insulating layer 300 and the third lower insulating layer 310 are formed, by repeatedly performing the process.

In this case, the third upper insulating layer 300 and the third lower insulating layer 310 are subjected to the desmear treatment to include the surface on which the surface roughness is formed.

Further, the top circuit layer 351 having a top seed pattern 335 and a bottom circuit layer 341 having the bottom seed pattern 325 may be formed on the surfaces of the third upper insulating layer 300 and the third lower insulating layer 310, respectively, that are subjected to the desmear treatment.

After the top circuit layer 351 and the bottom circuit layer 341 are formed, the first surface treating film 355 or the second surface treating film 365 are formed on the top circuit layer 351 and the bottom circuit layer 341.

Therefore, as illustrated in FIG. 3E, the multi-layer type printed circuit board formed to have a structure in which six circuit layers 351, 285, 261, 271, 295, and 341 and four insulating layers 260, 270, 300, and 310 are symmetrically to each other, based on the first insulating layer 220 may be implemented.

Further, the method of manufacturing a multi-layer printed circuit board according to another preferred embodiment of the present invention may implement the multi-layer printed circuit board having six or more circuit layers and four or more insulating layers.

Therefore, the method of manufacturing a multi-layer printed circuit board according to another preferred embodiment of the present invention forms the printed circuit board precursor having the multi-layer structure in a both surfaces direction of the carrier substrate 10 using the carrier substrate 10 and the dry film pattern, thereby improving the production efficiency of the multi-layer type printed circuit board.

According to the preferred embodiments of the present invention, the multi-layer type printed circuit board can easily include the pillar for electrical connection instead of the vias formed by the laser according to the prior art, thereby saving the manufacturing costs and improving the integration of the circuit.

According to the preferred embodiments of the present invention, the method of manufacturing a multi-layer type printed circuit board can easily manufacture the multi-layer type printed circuit board including the plurality of circuit layers electrically connected by the plurality of pillars using the carrier substrate and the dry film pattern, thereby resolving the problems of the machining time and the manufacturing costs occurring while forming the vias using a laser according to the prior art.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A multi-layer type printed circuit board, comprising:
a first insulating layer including at least one first pillar;
a plurality of insulating layers laminated in a both surfaces direction of the first insulating layer, each including at least one circuit layer and at least another pillar connected to the circuit layer; and
a plurality of outermost circuit layers disposed on an outer surface of the outermost insulating layer, while contacting an outermost pillar disposed on an outermost insulating layer among the plurality of insulating layers,
wherein the circuit layer and another pillar each formed in a both surfaces direction of the first insulating layer are disposed in a symmetrical form to each other based on the first insulating layer.

2. The multi-layer type printed circuit board as set forth in claim 1, wherein the first insulating layer includes a glass cloth, and
the first insulating layer and the plurality of insulating layers are made of different materials.

3. The multi-layer type printed circuit board as set forth in claim 1, wherein the plurality of insulating layers have a surface roughness disposed on a surface on which the circuit layer is provided.

4. The multi-layer type printed circuit board as set forth in claim 1, wherein the circuit layer and another pillar each are sequentially laminated in a both surfaces direction based on a first pillar of the first insulating layer and is provided in a symmetrical form to each other based on the first pillar.

5. The multi-layer type printed circuit board as set forth in claim 1, wherein the outermost circuit layer is provided with a first surface treating film of any one of an organic solderability preservative (OSP) treating film, a black oxide film, and a brown oxide film, instead of a solder resist (SR) or a second surface treating film of any one of a gold plating film, an electrolytic gold plating film, an electroless gold plating film, or an electroless nickel immersion gold (ENIG) film.

6. A method of manufacturing a multi-layer type printed circuit board, comprising:
(A) preparing a carrier substrate including at least one copper foil disposed on one surface or both surfaces of an insulating plate;
(B) forming a multi-layer type printed circuit board precursor on one surface or both surfaces of the carrier substrate;
(C) separating the carrier substrate; and
(D) laminating a plurality of other insulating layers sequentially including other circuit layers and other pillars on an outer surface of the multi-layer printed circuit board precursor.

7. The method as set forth in claim 6, further comprising:
(E) forming an outermost circuit layer on an outermost insulating layer of the other insulating layers; and
(F) forming a first surface treating film or a second surface treating film on the outermost circuit layer.

8. The method as set forth in claim 7, wherein the first surface treating film is formed of any one of an organic solderability preservative (OSP) treating film, a black oxide film, and a brown oxide film, instead of a solder resist (SR), and
the second surface treating film is formed of any one of a gold plating film, an electrolytic gold plating film, an electroless gold plating film, and electroless nickel immersion gold (ENG) film.

9. The method as set forth in claim 6, wherein the step (B) includes:
(B-1) forming a plurality of first pillars by performing the electrolytic copper plating on a first dry film pattern formed on one surface or both surfaces of the carrier substrate;
(B-2) peeling off the first dry film pattern;
(B-3) forming a first insulating layer having a thickness equal to or larger than a height of the first pillar on one surface or both surfaces of the carrier substrate;
(B-4) performing a polishing and cutting process on the first insulating layer so as to expose the first pillar;
(B-5) forming a seed layer on the outer surface of the first insulating layer on which the first pillar is exposed by using a PVD or CVD method;
(B-6) forming a dry film pattern for forming a first circuit layer on the seed layer;
(B-7) forming the first circuit layer by plating and peeling off copper on the dry film pattern for forming the first circuit layer;
(B-8) forming a second dry film pattern on the outer surface of the first insulating layer including the first circuit layer;
(B-9) forming a second pillar connected with the first circuit layer by plating and peeling off copper on the second dry film pattern;
(B-10) removing a non-overlapping seed layer on the first circuit layer by etching so as to form an overlapping seed pattern on the first circuit layer;
(B-11) forming a second insulating layer having a thickness equal to or larger than the overall height from the seed pattern to the second pillar; and
(B-12) performing the polishing and cutting process on the second insulating layer so as to expose the second pillar.

10. The method as set forth in claim 9, wherein in steps (B-1), (B-7), and (B-9), the copper is plated by any one of CVD, PVD, a subtractive method, an additive method using electroless copper plating or electrolytic copper plating, SAP and MSAP.

11. The method as set forth in claim 6, wherein the insulating layer of the multi-layer type printed circuit board is formed, including a glass cloth, and
the insulating layer of the multi-layer type printed circuit board precursor and the other insulating layers are made of different materials.

12. The method as set forth in claim 6, wherein the step (D) includes:
performing desmear treatment on the other insulating layers.

13. The method as set forth in claim 9, wherein the steps (B-4) and (B-12) are performed by using any one of belt-sander, end-mill, ceramic buff, and chemical mechanical polishing (CMP).

14. The method as set forth in claim 6, wherein the step (B) includes:
(B-1) forming a plurality of first pillars by plating copper on a first dry film pattern formed on one surface or both surfaces of the carrier substrate;
(B-2) peeling off the first dry film pattern;
(B-3) forming a first insulating layer having a thickness equal to or larger than a height of the first pillar on one surface or both surfaces of the carrier substrate; and
(B-4) performing a polishing and cutting process on the first insulating layer so as to expose the first pillar.

15. The method as set forth in claim 14, wherein in step (B-1), the copper is plated by any one of CVD, PVD, a subtractive method, an additive method using electroless copper plating or electrolytic copper plating, SAP and MSAP.

16. The method as set forth in claim 14, wherein the step (B-4) is performed by using any one of belt-sander, end-mill, ceramic buff, and chemical mechanical polishing (CMP).
